(19) United States
(12) Patent Application Publication
(10) Pub. No.: US 2013/0285127 A1
(43) Pub. Date: Oct. 31, 2013

(54) semiconductor structure and method of manufacturing the same

(71) Applicants: Huaxiang Yin, Beijing (CN); Qiuxia Xu, Beijing (CN); Dapeng Chen, Beijing (CN)

(72) Inventors: Huaxiang Yin, Beijing (CN); Qiuxia Xu, Beijing (CN); Dapeng Chen, Beijing (CN)

(73) Assignee: INSTITUTE OF MICROELECTRONICS, CHINESE ACADEMY OF SCIENCES, Chaoyang District, Beijing (CN)

(21) Appl. No.: 13/641,857

(22) PCT Filed: Apr. 26, 2012
(86) PCT No.: PCT/CN12/74773

§ 371 Date: Oct. 17, 2012

(51) Int. Cl. H01L 29/66; H01L 29/78

(52) U.S. Cl. CPC H01L 29/66477; H01L 29/78
USPC 257/288; 438/299

(57) ABSTRACT

The present application discloses a method for manufacturing a semiconductor structure, comprises the following steps: providing a substrate and forming a gate stack on the substrate; forming an offset spacer surround the gate stack and a dummy spacer surround the offset spacer; forming the S/D region on both sides of the dummy spacer; removing the dummy spacer and portions of the offset spacer on the surface of the substrate; forming a doped spacer on the sidewall of the offset spacer; forming the S/D extension region by allowing the dopants in doped spacer into the substrate; removing the doped spacer. Accordingly, the present application also discloses a semiconductor structure. In the present disclosure the S/D extension region with high doping concentration and shallow junction depth is formed by the formation of a heavily doped doped spacer, which can be removed in the subsequent procedures, in order to efficiently improve the performance of the semiconductor structure.

This application claims priority to the Chinese Patent Application No. 201210074860.0, filed on Mar. 20, 2012, entitled “semiconductor structure and method for manufacturing the same”, which is incorporated herein by reference in its entirety.

### TECHNICAL FIELD

The present disclosure relates to the field of semiconductor technology, and in particular, to a semiconductor structure and a method for manufacturing the same.

### BACKGROUND

Source/Drain (S/D) extension region plays an important role in controlling the short channel effect in MOS device and in improving the device driver capability.

S/D extension region is directly adjacent to the channel conductivity zone. With the continuous decrease in gate length, the requirement in S/D extension region depth keeps decreasing in order to suppress the increasingly serious short channel effect. However, the decrease in S/D extension region depth makes the resistance become larger. If the series resistance of the S/D extension region is not reduced in time, the parasitic resistance of the S/D extension region will become a big issue in device conduction resistance, and thus will affect or diminish the advantages in drift mobility improvement and channel equivalent resistance decrease by the channel strain technology.

In currently used technologies, methods including ultra-low energy implantation (such as with implantation energy less than 1 keV) and high energy transient laser annealing etc. are usually utilized to reduce the S/D extension region depth and increase the activation concentration to lower the resistance. However, with further development in the technology node of integrated circuit, there are increasingly high requirement in the process parameters of S/D extension region for device performance, and the technical difficulties in the above methods are also increasing, especially in the technologies for 22 nm and below.

Therefore, a semiconductor structure and a method for manufacturing the same is expected to enable the semiconductor structure with both high doping concentration and shallow junction depth in S/D extension region.

### SUMMARY OF THE DISCLOSURE

The present disclosure provides a semiconductor structure and a method for manufacturing the same to solve the above problems.

According to one aspect of the present disclosure, a method for manufacturing a semiconductor structure is provided, comprising:

a) providing a substrate and forming a gate stack on the substrate;
b) forming an offset spacer surround the gate stack and a dummy spacer surround the offset spacer;
c) forming the S/D region on both sides of the dummy spacer;
d) removing the dummy spacer and portions of the offset spacer on the surface of the substrate;
e) forming a doped spacer on the sidewall of the offset spacer;
f) forming the S/D extension region by allowing the dopants in doped spacer into the substrate;
g) removing the doped spacer.

According to another aspect of the present disclosure, a semiconductor structure is also provided, comprising:

a substrate;
a gate stack, which is located on the substrate;
a spacer, which is located on the sidewall of the gate stack;
a S/D extension region, which is located in the substrate on both sides of the spacer;
a S/D region, which is located in the substrate on both sides of the S/D extension region.

The technical solutions according to the present disclosure will have the following advantages over the prior art. The S/D extension region with high doping concentration and shallow junction depth can be formed by the formation of a heavily doped doped spacer surround the sidewall of the gate stack on substrate and by allowing the dopants into the substrate with laser radiation, etc. and thereby the performance of the semiconductor structure can be efficiently improved.

### BRIEF DESCRIPTION OF THE DRAWINGS

Other characteristics, objectives and advantages will become more obvious after reading the detailed description of the non-limiting embodiments with reference to the following attached drawings, in which:

FIG. 1 is a schematic flow chart showing the method for manufacturing a semiconductor structure according to the embodiment of the present disclosure;

FIGS. 2-17 are schematic cross-sectional views of the various stages for manufacturing the semiconductor structure according to the flow chart in FIG. 1.

### DETAILED DESCRIPTION

Exemplary embodiments of the present disclosure will be described in more details below.

Some embodiments are illustrated in the attached drawings, in which the same or similar reference numbers represent the same or similar elements or the components having the same or similar functions. The following embodiments described with reference to the drawings are only exemplary for explaining the present invention, and therefore shall not be construed as limiting the present invention. The disclosure below provides many different embodiments or examples to implement different structures of the present invention. In order to simplify the disclosure of the present invention, components and settings of specific examples are described below. Obviously, they are merely exemplary, and are not intended to limit the present invention. In addition, reference numbers and/or letters can be repeated in different examples of the invention. This repetition is used only for simplicity and clarity, and does not indicate any relationship between the discussed embodiments and/or settings. Furthermore, the invention provides a variety of specific examples of processes and materials, but it is obvious for a person of ordinary skill in the art that other processes can be applied and/or other materials can be used. In addition, the following description of a structure where a first feature is “on” a second feature can comprise examples where the first and second feature are in direct contact, and also can comprise examples where additional features are formed between the first and second features so that the first and second features may not be in direct contact.

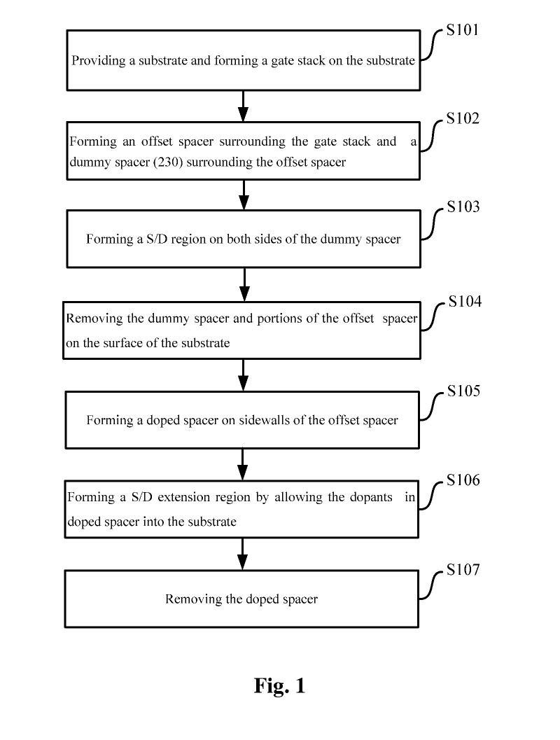

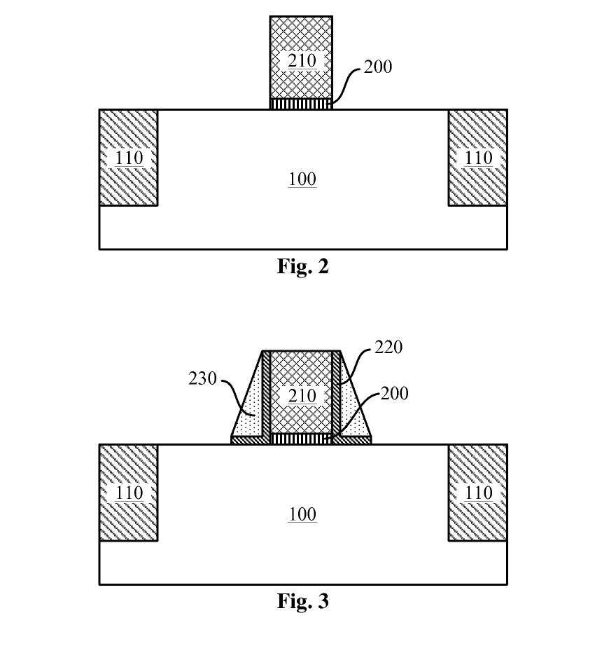

According to one aspect of the present disclosure, a method for manufacturing a semiconductor structure is provided. The method for manufacturing a semiconductor structure in FIG. 1 will be illustrated in more detail with reference to one embodiment according to the present disclosure in combination with FIGS. 2 to 17. As shown in FIG. 1, the method for manufacturing the semiconductor structure according to the present disclosure comprises the following steps.

In Step S101, a substrate 100 is provided, and a gate stack is formed on the substrate 100.

In particular, as shown in FIG. 2, a substrate 100 is provided first. In the present embodiment, the substrate 100 is silicon substrate (such as silicon wafers). According to the design requirement known in the existing technology (such as P-type substrate or N-type substrate), the substrate 100 can comprise all kinds of doping configurations. In other embodiments, the substrate 100 can comprise other fundamental semiconductors (such as materials in Group III-V), for example, germanium. Or substrate 100 can comprise compound semiconductor, such as silicon carbide, gallium arsenide, indium arsenide. Typically substrate 100 is with, but not limited to, a depth of several hundred microns, for example, in the depth range of 400-800 μm.

Then, a quarantine region is formed in the substrate 100, such as a shallow trench isolation (STI) structure 110, in order to isolate electrically the continuous FET devices.

Next, a gate stack is formed on the substrate 100. First, a gate dielectric layer 200 is formed on the substrate 100. In the present embodiment, the gate dielectric layer 200 can be silicon oxide or silicon nitride and the combinations thereof. In other embodiments, the gate dielectric layer 200 can also be high K dielectric, such as HfO₂, HfSiO, HfSiON, HfTaO, HfTiO, HfZrO, HfLaO, HfLaSiO, Al₂O₃, La₂O₃, ZrO₂, and LaAlO, or combinations thereof, or it can comprise the combinational structure of the high K dielectric and silicon oxide or silicon nitride with a depth of 1-15 nm. Then, a gate 210 is formed on the gate dielectric layer 200. The gate 210 can be metal gate, such as deposition of metal nitrides comprising MₓN_{y}, MₓSi_{y}N_{z}, MₓAl_{y}N_{z}, and MaAlₓSi_{y}N_{z}, or combinations thereof, where M can be Ta, Ti, Hf, Zr, Mo, and W, or combinations thereof, and/or metal or metal alloy comprising Co, Ni, Cu, Al, Pd, Pt, Ru, Re, Mo, Ta, Ti, Hf, Zr, W, Ir, Eu, Nd, Er, and La, or combinations thereof. The gate 210 can also be metal silicide, such as NiSi, CoSi, and TiSi, etc. with a depth of 10-150 nm. In another embodiment, the gate 210 can also be a dummy gate, such as formed by decomposition of polysilicon, poly-SiGe, amorphous silicon, and/or by doping undoped silicon oxide, silicon nitride, silicon oxynitride, silicon carbide, or even metals. In another embodiment, the gate stack can be a dummy gate only without the gate dielectric layer 200, where the gate dielectric layer can be formed after removing the dummy gate in the subsequent gate replacement process.

The subsequent steps will be explained by an example of the formation of the dummy gate stack by the gate dielectric layer 200 and the dummy gate 210 in below.

In step S102, an offset spacer 220 surrounding the gate stack and a dummy spacer 230 surrounding the offset spacer 220 are formed.

In particular, first, the first insulation layer (not shown) is decomposed on the substrate 100, and then the second insulation layer (not shown) is decomposed on the first insulation layer, wherein the material for the first insulation layer is different from that for the second insulation layer. The materials for the first and/or second insulation layers comprise silicon nitride, silicon oxide, silicon oxynitride, and silicon carbide, or the combinations thereof, and/or other suitable materials. Then, the second and first insulation layers are etched to form the dummy spacer 230 and offset spacer 220, as shown in FIG. 3, wherein the spacer 220 is located on the substrate 100 and surrounded on the sidewall of the dummy gate stack with a small depth. The part of substrate 100 located on both sides of the dummy gate stack is covered by the offset spacer 220 and dummy spacer 230. In the subsequent steps, part or all of the covered region of the substrate 100 will be used to for the S/D extension region.

In step S103, a S/D region is formed on both sides of the dummy spacer 230.

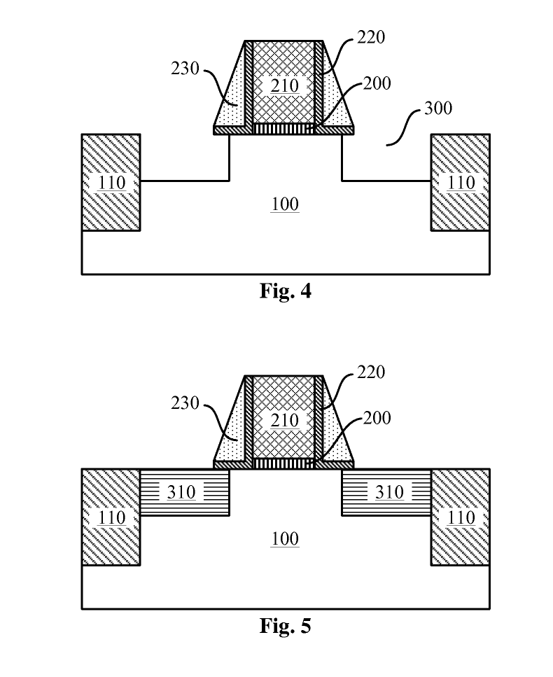

In particular, as shown in FIG. 4, the substrate 100 on both sides of the dummy spacer 230 is etched to form the first trench 300 by anisotropic dry and/or wet etching using the dummy spacer 230 as a mask. Preferably, alternately using isotropic and anisotropic etching modes, not only the SOI substrate 100 on both sides of the dummy spacer 230 but also the part of substrate 100 under the dummy spacer 230 are etched to make the formed first trench 300 as close as possible to the center of the channel. The wet etching process comprises using tetramethyl ammonium hydroxide (TMAH), potassium hydroxide (KOH), or other suitable etching solution; the dry etching process comprises using sulfur hexafluoride (SF6), bromide hydrogen (HBr), hydrogen iodide (HI), chlorine, argon, and helium, or the combinations thereof, and/or other suitable materials. After the formation of the first trench 300, as shown in FIG. 5, the substrate 100 is used as a seed crystal and the first trench 300 is filled by methods such as epitaxial growth and the filled materials are doped to form the embedded S/D region 310. Preferably, the lattice constant of the material to form S/D region 310 is not equal to the lattice constant of the material for the substrate 100. For PMOS devices the lattice constant of S/D region 310 is slightly higher than the lattice constant of the substrate 100 to make compressive stress to the channel, for example, Si₁₋ₓGeₓ, where X is in the range of 0.1˜0.7, such as 0.2, 0.3, 0.4, 0.5, or 0.6; for NMOS devices the lattice constant of S/D region 310 is slightly lower than the lattice constant of the substrate 100 to make tensile stress to the channel, for example, Si:C, where the number of atoms percentage of C is in the range of 0.2%-2%, such as 0.5%, 1%, or 1.5%. After filling the first trench 300, the S/d region 310 is formed either by methods such as ion implantation or in-situ doping, or by simultaneous in-situ doping in the process of epitaxial growth. The dopant is boron for Si₁₋ₓGeₓ and phosphorus or arsenic for Si:C.

In other embodiments, the S/D region is formed on both sides of the dummy gate stack by implantation of P-type or N-type dopants or impurities to the substrate 100.

The semiconductor structure is annealed to activate the dopant in the S/D region 310, wherein the annealing comprises rapid thermal annealing, spike annealing, and other suitable annealing. Surely annealing can also be done to the semiconductor structure after the formation of the S/D extension region.

In step S104, the dummy spacer 230 and portions of the offset spacer 220 located on the surface of the substrate 100 are removed.

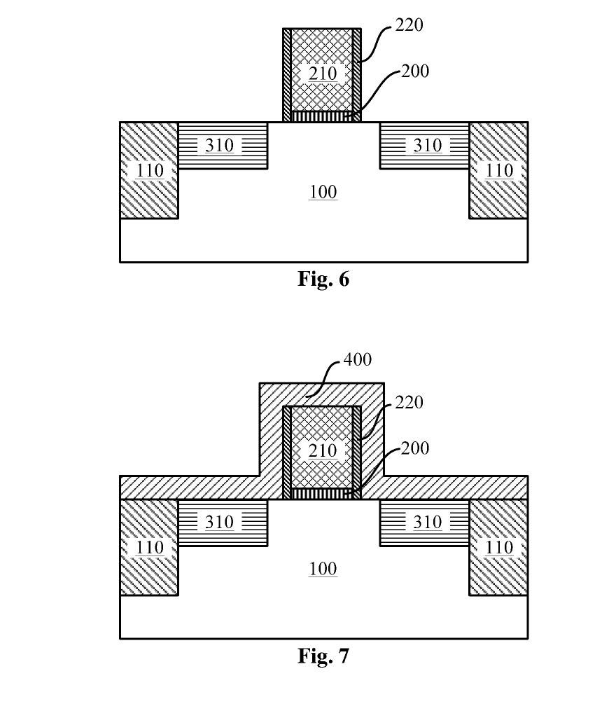

In particular, as shown in FIG. 6, the dummy spacer 230 and portions of the offset spacer 220 located on the surface of the substrate 100 are removed by selective etching to expose the part of substrate 100 between the dummy gate stack and the S/D region 310. The offset spacer 220 on the sidewall of the dummy spacer is not etched to protect the dummy gate stack.

In step S105, a doped spacer 410 is formed on the sidewall of the offset spacer 220.

In particular, as shown in FIG. 7, a doped layer 400 is formed on the surface of the semiconductor structure by decomposition, wherein the doped layer 400 comprises but not limited to heavily doped amorphous silicon, polycrystalline silicon, borosilicate glass (BSG), or phosphosilicate glass (PSG). The dopant in the doped layer 400 is P-type for PMOS devices, such as boron; the dopant in the doped layer 400 is N-type for NMOS devices, such as arsenic. The doping concentration of the doped layer 400 is in the range of 1×10¹⁹−1×10²¹ cm⁻³.

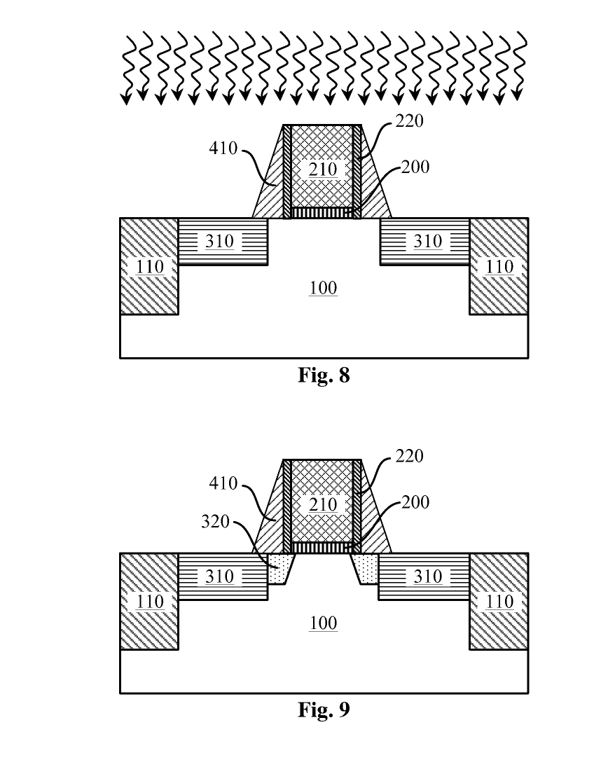

Then, as shown in FIG. 8, a doped spacer 410, which covers the area of substrate 100 located between the dummy gate stack and the S/D region 310, is formed by removing part of the doped layer 400 by etching and keeping the part of the doped layer 400 surrounding the sidewall of the dummy spacer.

In step S106, the S/D extension region 320 is formed by allowing the dopants in doped spacer 410 into the substrate 100.

In particular, as indicated by the arrow in FIG. 8, radiation such as lasers is carried out on the doped spacer 410. The S/D extension region 320 is formed on the substrate 100 between the offset spacer 220 and the S/D region 310 by controlling the radiation time and radiation intensity and by allowing the dopants in the doped spacer 410 to diffuse into the substrate 100 below, as shown in FIG. 9. Furthermore, because of the high doping concentration in the doped spacer, lateral diffusion also happens during the downward diffusion. Normally the lateral diffusion is required to exceed the depth of the offset spacer; therefore, dopants will diffuse laterally into the channel region. The so-formed S/D extension region 320 is with shallow junction depth yet high doping concentration, wherein the doping concentration is in the range of 5×10¹⁸−5×10²⁰ cm⁻³ and the junction depth is in the range of 3-50 nm, comparing to the conventionally formed S/D extension region by ion implantation,

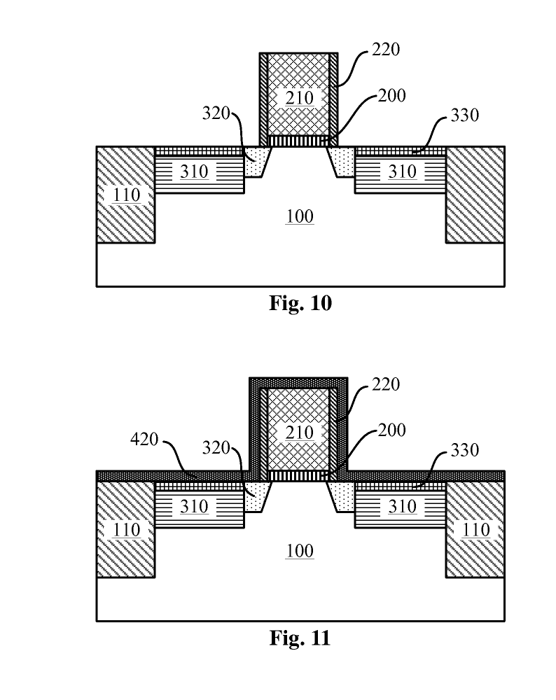

In step S107, as shown in FIG. 10, the doped spacer 410 is removed.

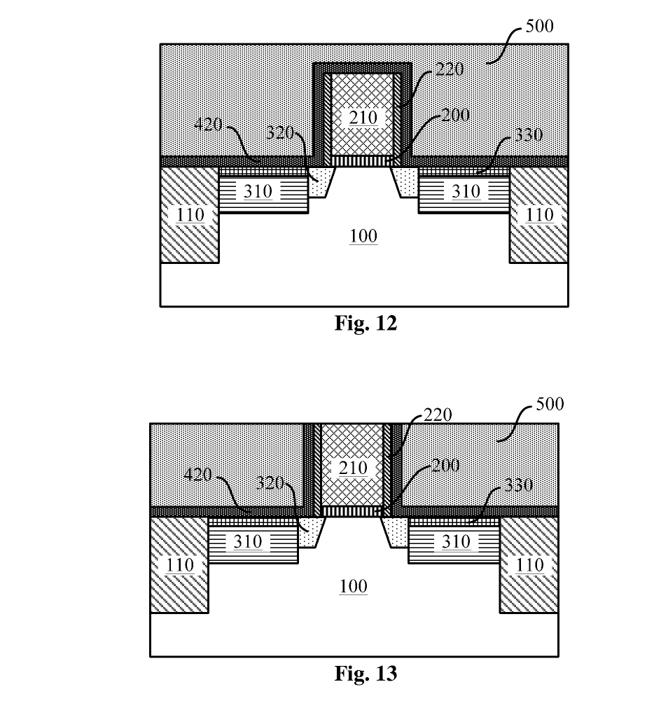

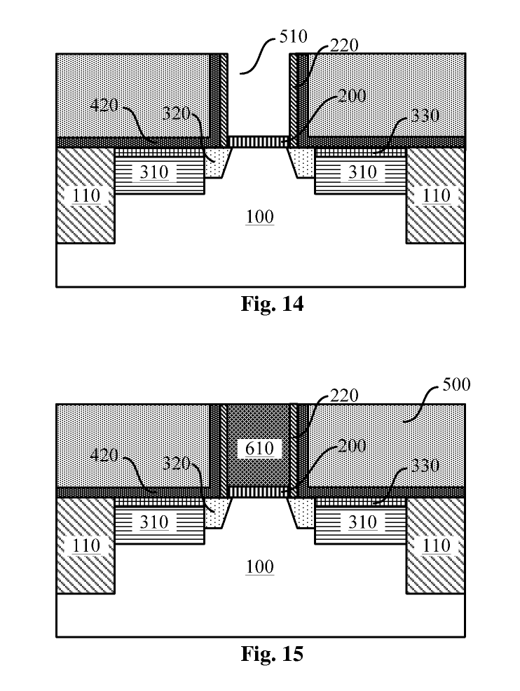

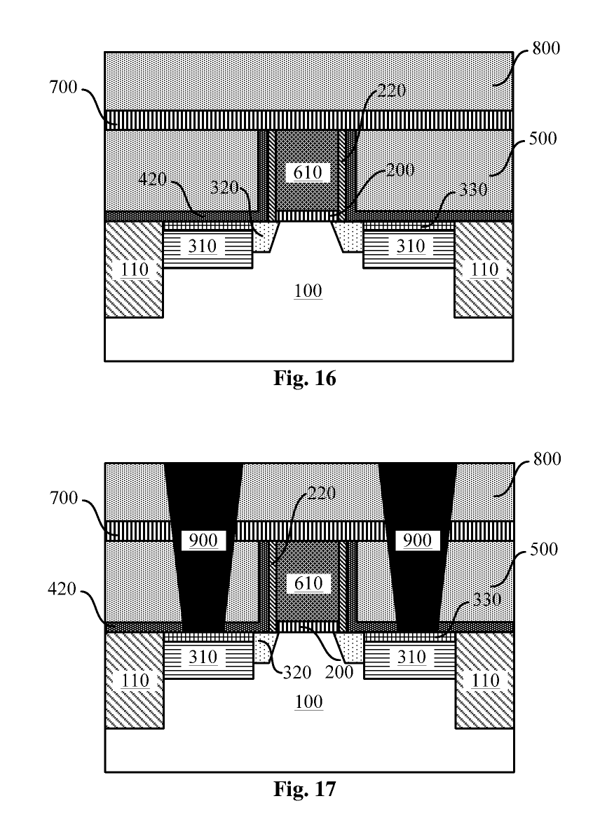

Consequently manufacturing the semiconductor structure is finished according to the convention semiconductor manufacturing process, as referred to FIG. 10-17. Specifically as below: as shown in FIG. 10, a metal silicide layer is formed on the surface of the S/D region 310 to reduce the contact resistance; as shown in FIG. 11, a contact etching stop layer 420 is formed on the semiconductor structure; then, as shown in FIGS. 12 and 13, a first interlayer dielectric layer 500 is formed by decomposition to cover the contact etching stop layer 420 and planarization operation is carried out to expose the dummy gate stack 210; next, as shown in FIG. 14, a second trench 510 is formed by removing the dummy gate stack 210; then, as shown in FIG. 15, a gate electrode layer 610 is formed in the second trench 510; finally, as shown in FIGS. 16 and 17, a cap layer 700 and a second interlayer dielectric layer 800 are formed on the first interlayer dielectric layer 500, and a contact plug 900 penetrating the second interlayer dielectric layer 800, the cap layer 700, and the first interlayer dielectric layer 500 is also formed.

The present disclosure will have the following advantages over the currently used technology. The S/D extension region with high doping concentration and shallow junction depth can be formed by the formation of a heavily doped doped spacer surround the sidewall of the gate stack on substrate and by allowing the dopants into the substrate with laser radiation, etc. and thereby the performance of the semiconductor structure can be efficiently improved.

According to another aspect of the present disclosure, a semiconductor structure is also provided, as referred to FIG. 17. According to the figure, the semiconductor structure comprises:

A substrate 100;

A gate stack, which is located on the substrate 100;

A spacer 220, which is located on the sidewall of the gate stack;

A S/D extension region 320, which is located in the substrate 100 on the bottom and both sides of the spacer 220;

A S/D region 310, which is located in the substrate 100 on both sides of the S/D extension region 320.

In particular, in the present embodiment, the substrate 100 is silicon substrate (such as silicon wafers). According to the design requirement known in the existing technology (such as P-type substrate or N-type substrate), the substrate 100 can comprise all kinds of doping configurations. In other embodiments, the substrate 100 can comprise other fundamental semiconductors (such as materials in Group III-V), for example, germanium. Or substrate 100 can comprise compound semiconductor, such as silicon carbide, gallium arsenide, indium arsenide. Typically substrate 100 is with, but not limited to, a depth of several hundred microns, for example, in the depth range of 400-800 μm. A quarantine region is located in the substrate 100, such as a shallow trench isolation (STI) structure 110, in order to isolate electrically the continuous FET devices.

A gate stack is located on the substrate 100. As shown in the figures, the gate stack comprises a gate dielectric layer 200 and a gate electrode layer 610, wherein the gate dielectric layer 200 is located on the substrate 100 and the gate electrode layer 610 is located on the gate dielectric layer 200. In the present embodiment, the gate dielectric layer 200 is high K dielectric, such as HfO₂, HfSiO, HfSiON, HfTaO, HfTiO, HfZrO, Hf LaO, HfLaSiO, Al₂O₃, La₂O₃, ZrO₂, and LaAlO, or combinations thereof, or it can comprise the combinational structure of the high K dielectric and silicon oxide or silicon nitride, with a depth of 1-15 nm. The gate electrode layer 610 can be metal nitrides comprising MₓN_{y}, MₓSi_{y}N_{z}, MₓAl_{y}N_{z}, and MaAlₓSi_{y}N_{z}, or combinations thereof, where M can be Ta, Ti, Hf, Zr, Mo, and W, or combinations thereof, and/or metal or metal alloy comprising Co, Ni, Cu, Al, Pd, Pt, Ru, Re, Mo, Ta, Ti, Hf, Zr, W, Ir, Eu, Nd, Er, and La, or combinations thereof. The gate electrode layer 610 can also be metal silicide, such as NiSi, CoSi, and TiSi, etc. with a depth of 10-150 nm.

A spacer 220 is located on the sidewall of the gate stack and the materials for the spacer 220 comprise silicon nitride, silicon oxide, silicon oxynitride, and silicon carbide, or the combinations thereof, and/or other suitable materials.

The S/D extension region 320 is located in the substrate 100 on the bottom and both sides of the spacer 220. The S/D region 310 is next to the S/D extension region 320, or it is located in the substrate 100 on both sides of the S/D extension region 320. According to the type of the semiconductor structure, the S/D extension region 320 and the S/D region 310 comprise P-type or N-type dopants or impurities (for example, the dopant is boron for PMOS devices and the dopant is arsenic for NMOS devices), wherein the doping concentration for the S/D extension region is in the range of 5×10¹⁸−5×10²° cm⁻³ and the junction depth is in the range of 3-50 nm. The doping concentration for the S/D region 310 is higher than that for the S/D extension region 320. In the present embodiment, the S/D region 310 is embedded S/D region. The lattice constant of the materials for the S/D region 310 is slightly higher or lower than the lattice constant of the materials for the substrate 100 to apply stress to the channel to improve the mobility of the charge carrier in the channel. For PMOS devices the lattice constant of S/D region 310 is slightly higher than the lattice constant of the substrate 100 to apply compressive stress to the channel, for example, the S/D region 310 can be Si₁₋ₓGeₓ, where X is in the range of 0.1˜0.7, such as 0.2, 0.3, 0.4, 0.5, or 0.6; for NMOS devices the lattice constant of S/D region 310 is slightly lower than the lattice constant of the substrate 100 to apply tensile stress to the channel, for example, the S/D region 310 can be Si:C, where the number of atoms percentage of C is in the range of 0.2%-2%, such as 0.5%, 1%, or 1.5%. Preferably, a metal silicide layer 330 is located on the surface of the S/D region 310 to reduce the contact resistance of the semiconductor structure.

The semiconducting structure also comprises a contact etching stop layer 420, a first interlayer dielectric layer 500, a cap layer 700, a second interlayer dielectric layer 800 and a contact plug 900, wherein the contact etching stop layer 420 is located on the sidewall of the spacer 220 and on the surface of the substrate 100. The first interlayer dielectric layer 500, the cap layer 700, and the second interlayer dielectric layer 800 are located sequentially on the contact etching stop layer 420. The contact plug 900 penetrates through the second interlayer dielectric layer 800, the cap layer 700, the first interlayer dielectric layer 500, and the contact etching stop layer 420, and contacts electrically with the S/D region (310).

The semiconductor structure provided in the present disclosure efficiently improves the performance of the semiconductor structure by the high doping concentration and the shallow junction depth of the S/D extension region.

Although the exemplified embodiments and the advantages thereof have been illustrated in detail, it is understood that any modification, replacement and change can be made to these embodiments without departing from the spirit of the invention and the scope defined in the attaching claims. As to other examples, a skilled technician in the art can easily understand that the order of the process steps can be modified without falling outside the protection scope of the invention.

In addition, the application fields of the invention is limited to the process, mechanism, fabrication, material compositions, means, methods and/or steps in the particular embodiments as given in the description. From the disclosure of the invention, a skilled technician in the art can easily understand that, as for the process, mechanism, fabrication, material compositions, means, methods and/or steps at present or to be developed, which are carried out to realize substantially the same function or obtain substantially the same effects as the corresponding examples described according to the invention do, such process, mechanism, fabrication, material compositions, means, methods and/or steps can be applied according to the invention. Therefore, the claims attached to the invention are intended to encompass the process, mechanism, fabrication, material compositions, means, methods and/or steps into the protection scope thereof.

1. A method for manufacturing a semiconductor structure, comprising:
a) providing a substrate and forming a gate stack on the substrate;
b) forming an offset spacer surrounding the gate stack and a dummy spacer surrounding the offset spacer;
c) forming a S/D region on both sides of the dummy spacer;
d) removing the dummy spacer and portions of the offset spacer on the surface of the substrate;
e) forming a doped spacer on sidewalls of the offset spacer;
f) forming a S/D extension region by allowing the dopants in doped spacer into the substrate; and
g) removing the doped spacer.

2. The method according to claim 1, wherein the step e) comprises:
forming a doped layer to cover the semiconducting structure;
etching the doped layer to form a doped spacer surrounding the gate stack.

3. The method according to claim 2, wherein:
the materials for the doped layer are selected from the group consisting of amorphous silicon, polycrystalline silicon, borosilicate glass, phosphosilicate glass, and combinations thereof.

4. The method according to claim 3, wherein:
if the type of the semiconductor structure is PMOS, then the dopant in the doped layer is P-type;
if the type of the semiconductor structure is NMOS, then the dopant in the doped layer is N-type.

5. The method according to claim 4, wherein the doping concentration of the doped layer is in the range of 1×10¹⁹−1×10²¹ cm⁻³.

6. The method according to claim 1, wherein:
eradiate the doped spacer by an excimer laser to allow the dopants in doped spacer into the substrate.

7. The method according to claim 1, wherein the doping concentration in the S/D extension region is in the range of 5×10¹⁸−5×10²⁰ cm⁻³ and the junction depth is in the range of 3-50 nm.

8. The method according to claim 1, wherein the step c) comprises:
etching the substrate by using the gate stack with the dummy spacer as a mask to form the first trench on both sides of the gate stack;
epitaxially growing the S/D region in the first trench by using the substrate as a seed crystal.

9. The method according to claim 8, wherein the lattice constant of the material for S/D region is not equal to the lattice constant of the material for the substrate.

10. The method according to claim 1, wherein the gate stack comprises a gate dielectric layer and a dummy gate.

11. The method according to claim 10, wherein after step g), the method further comprises:
forming a metal silicide layer on the surface of the S/D region;
forming a contact etching stop layer that covers the whole semiconductor structure and the first interlayer dielectric layer, and performing a planarization operation to expose the dummy gate;
forming the second trench by removing the dummy gate, and forming a gate electrode layer in the second trench;
forming a cap layer and the second interlayer dielectric layer on the first interlayer dielectric layer; and
forming a contact plug that penetrates through the second interlayer dielectric layer, the cap layer, the first interlayer dielectric layer, and the contact etching stop layer.

12. A semiconductor structure, comprising:
a substrate;
a gate stack, which is located on the substrate;
a spacer, which is located on sidewalls of the gate stack;
a S/D extension region, which is located in the substrate on the bottom and both sides of the spacer;
a S/D region, which is located in the substrate on both sides of the S/D extension region.

13. The semiconducting structure according to claim 12, wherein: the doping concentration of the S/D extension region (320) is in the range of 5×10¹⁸−5×10²⁰cm⁻³ and the junction depth is in the range of 3-50 nm.

14. The semiconducting structure according to claim 12, wherein the S/D region is an embedded S/D region and the lattice constant of the material is not equal to the lattice constant of the material for the substrate.

15. The semiconducting structure according to claim 12, further comprising a metal silicide layer, a contact etching stop layer, a first interlayer dielectric layer, a cap layer, a second interlayer dielectric layer and a contact plug, wherein:
the metal silicide layer is located on the surface of the S/D region;
the contact etching stop layer is located on sidewalls of the spacer and on the surface of the substrate;
the first interlayer dielectric layer, the cap layer, and the second interlayer dielectric layer are located sequentially on the contact etching stop layer; and
the contact plug penetrates through the second interlayer dielectric layer, the cap layer, the first interlayer dielectric layer, and the contact etching stop layer, and contacts with the S/D region.

16. The semiconducting structure according to claim 13, further comprising a metal silicide layer, a contact etching stop layer, a first interlayer dielectric layer, a cap layer, a second interlayer dielectric layer, and a contact plug, wherein:
the metal silicide layer is located on the surface of the S/D region;
the contact etching stop layer is located on sidewalls of the spacer and on the surface of the substrate;
the first interlayer dielectric layer, the cap layer, and the second interlayer dielectric layer are located sequentially on the contact etching stop layer; and
the contact plug penetrates through the second interlayer dielectric layer, the cap layer, the first interlayer dielectric layer, and the contact etching stop layer, and contacts with the S/D region.
